(19) United States
(12) Patent Application Publication
(10) Pub. No.: US 2007/0253578 A1
(43) Pub. Date: Nov. 1, 2007

(54) System and method for adjusting microphone gain based on volume setting of a mobile device

(76) Inventors: Michael T. Verdecanna, Bayport, NY (US); David D. Landron, Coram, NY (US)

Correspondence Address: FAY KAPLUN & MARCIN, LLP, 15O BROADWAY, SUITE 702, NEW YORK, NY, 10038, US

(21) Appl. No.: 11/407,317

(22) Filed: Apr. 19, 2006

(51) Int. Cl. H03G 3/00; H03G 9/00

(52) U.S. Cl. 381/104; 381/102

(57) ABSTRACT

Described is a mobile device having a microphone to receive audible input and an audio circuit to transform the audible input into an electrical signal, the audio circuit including a variable gain amplifier to amplify the electrical signal, a gain of the variable gain amplifier being set based on a volume setting of the mobile device, the gain being inversely proportional to the volume setting.

### BACKGROUND INFORMATION

Existing microphone designs incorporate amplifier circuitry to apply a certain amount of gain to the input signal obtained by the microphone. The amplifier (“amp”) applies a gain to the signal before the signal reaches subsequent circuitry (e.g. amplifier, mixer, modulator, filter etc.). The circuitry involved in a amp is quite simple, however many voice-enabled mobile devices, including cellular phones, have a fixed gain amp, applying the same gain regardless of the input signal.

The use of a fixed gain amp in microphone circuitry has several shortcomings. The fixed gain amp does not discriminate as to the nature of the input signal. Hence, the gain applied by the amp may not be the optimal amplification for the type of input signal. This may result in an output signal from the amp that would not necessarily be optimal. Thus, there is a need for an improved method of amplifying signals received from a voice-enabled mobile device microphone.

### SUMMARY OF THE INVENTION

A mobile device having a microphone to receive audible input and an audio circuit to transform the audible input into an electrical signal, the audio circuit including a variable gain amplifier to amplify the electrical signal, a gain of the variable gain amplifier being set based on a volume setting of the mobile device, the gain being inversely proportional to the volume setting.

A method for receiving an audible signal, setting a gain of a variable gain amplifier, the gain being based on a volume setting of a mobile device in which the variable gain amplifier resides and converting the audible signal to an electrical signal, the converting including amplifying the electrical signal with the variable gain amplifier.

An arrangement including a receiving means to receive an audible input and a transforming means to transform the audible input to an electrical signal, the transforming means including a variable gain means to provide the electrical signal with a variable gain based on a volume setting.

### BRIEF DESCRIPTION OF DRAWINGS

FIG. 1 shows an exemplary embodiment of a system according to the present invention.

FIG. 2 shows an exemplary embodiment of a method according to the present invention.

FIG. 3 shows a further exemplary embodiment of a method according to the present invention.

### DETAILED DESCRIPTION

The present invention may be further understood with reference to the following description and the appended drawings. Disclosed is a system and method for applying a variable microphone gain in voice-enabled mobile devices depending on a volume setting of the mobile device. Although the present invention will be described with reference to a cellular phone microphone, it will be understood by those of ordinary skill in the art that the present invention may be used for any voice-enabled mobile device microphone design.

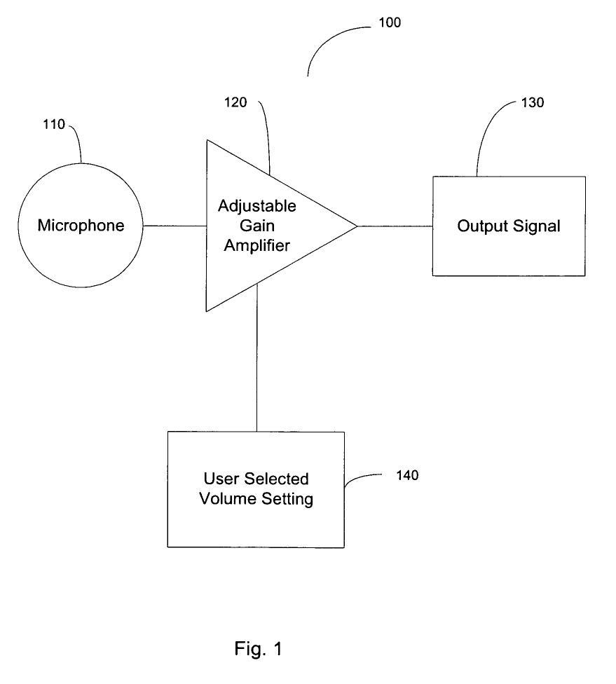

FIG. 1 shows an exemplary embodiment of a system 100 according to the present invention. The system 100 is a simplified block diagram of amplification circuitry that may be used in any voice-enabled mobile device. Voice-enabled mobile devices may include cellular phones, voice over internet protocol (VoIP) devices, personal data assistants (PDAs), laptop computers, mobile computing devices, etc. The system 100 may include a microphone 110, an adjustable gain amplifier 120, a user selected volume setting 140 and an output signal 130. Although system 100 is shown with a single variable gain amplifier, an alternative embodiment may include a network of switches and an array of fixed gain amplifiers with varying gains. Furthermore, additional circuitry that may be used in the implementation of the microphone may have been omitted for reasons of simplicity. Omitted circuitry may include filters, modulators, mixers, additional amplifiers, etc. Those of skill in the art will understand that the design for the microphone circuitry can be executed in various designs, is not limited to the simplified diagram given for the present invention, and is irrelevant for the implementation of the present invention.

The microphone 110 may receive any sounds in its vicinity. The microphone 110 may be implemented as any type of microphone known to those of skill in the art. The sounds/audio signals that microphone 110 may receive include the voice of the user and background noise from the environment in which the user is located. The microphone 110 converts the audio signals to electrical signals for further transmission. These electrical signals may be fed to an amplifier before reaching any subsequent circuitry. Traditionally, for devices such as cellular phones, the amplifier used has been a fixed gain amplifier. Having a single value of gain may not be optimal where the volume of the user's voice and ambient noise may differ according to the user's environment. A fixed gain amplifier causes the user's voice and the ambient noise to be amplified at the same level regardless of the volume of the user's voice and the volume of the ambient noise.

The exemplary embodiments of the present invention optimize the amplification of the signals received by the microphone 110. As seen in FIG. 1, the present invention utilizes an adjustable gain amplifier 120 in place of a fixed gain amplifier. Any amplifier circuitry may be used to implement the adjustable gain amplifier 120 from simple op-amp circuits to more complex integrated circuits (“ICs”). An alternative embodiment may utilize a switch network and an array of fixed-gain amplifiers of varying levels of gain in place of the adjustable gain amplifier. The amount of amplification applied to the signals received by the microphone 110 can be varied depending on the environment of the user. In an exemplary embodiment of the present invention, if the user is in an environment of low ambient noise and is thus speaking softly, a higher value of amplification can be applied to deliver a more optimal signal. In a further embodiment, if a user is speaking loudly in an environment with a high level of ambient noise, less amplification would be applied, reducing the amplification of the background noise and the user's voice. Varying the level of gain depending on the environment of the user would reduce background noise when the user is in high ambient noise environments and compensate for the voice level of the user whether it be high or low.

The amount of gain that is to be applied may be determined by the user selected volume setting 140 as shown in FIG. 1. The user selected volume setting 140 may be implemented in a variety of manners. In one exemplary embodiment, the level of amplification may be linked directly to the volume setting of the device, and apply a gain that is inversely proportional to the volume setting. In a first embodiment, the user volume setting is a manual setting set by the user. For example, a user of a cellular phone in a low ambient noise environment (e.g. an office) would likely have the volume setting at a low value. Thus, a low volume setting would result in a higher gain. Conversely, when a user is in an environment of high ambient noise (e.g. a manufacturing facility), the user would likely have the volume at a high value. Thus, a lower level of gain would be applied.

A further embodiment may incorporate user selectable profiles for different environments that are stored in the cellular phone. For example, the phone may include a series of profiles for various locations that may be predefined (e.g., high noise environment, low noise environment, etc) or defined by the user (e.g., home, office, warehouse, store floor, etc.), each of which includes a corresponding volume setting. The user may manually select the desired profile based on the user's location or there may be an automatic selection based on, for example, time of day, location determined by the mobile device or network (e.g., GPS location data, LAN location data, etc). The selection of any of these profiles may also be used in adjusting the gain of the adjustable gain amplifier 120. Thus, similar to the manual embodiment described above, if the office profile is associated with a low volume setting, the gain of the amplifier will be higher than if the volume setting was a high volume setting associated with, for example, a warehouse profile.

A further embodiment may incorporate the noise level measured using the microphone 110 (or an additional microphone). For example, prior to setting the gain of the amplifier 120, there may be circuitry in the mobile device that measures the ambient noise being received by the microphone 110. This ambient noise level may then be used to adjust both or either of the volume setting and/or the gain of the amplifier 120. The ambient noise measurement may be a continuous function or it may occur at various intervals depending on the current functionality of the mobile device, e.g., when the user selects a voice application.

The amplified signal is then output to subsequent circuitry, as shown in FIG. 1, as output signal 130. This output signal may be fed to other circuitry including a filter, a mixer, a modulator, an additional amplifier, a transmitter, etc.

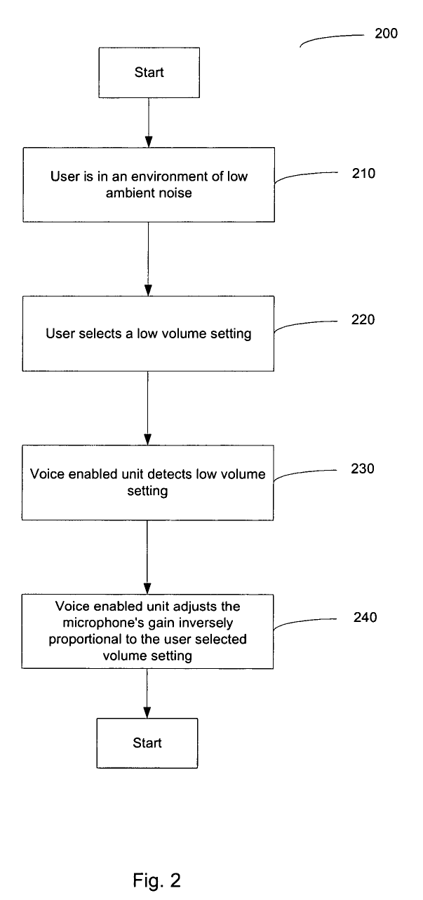

FIG. 2 shows a method according to the exemplary embodiment of the present invention that adjusts the gain of an amplifier according to user selected settings. The method is described with reference to the system described in FIG. 1. Those of skill in the art will understand that other systems having various configurations may be used to execute the exemplary method.

In step 210, the user of the device (e.g. cellular phone) enters an environment that has a low level of background noise. This may include settings such as an office, a school, a museum, a library, etc. In these types of settings, it is likely that the user of a cellular phone would use a lower volume setting on his/her phone and would be speaking at a softer volume.

In step 220, the user selects a low volume setting (e.g. user selected volume setting 140). This action may be accomplished in a variety of manners as described above, e.g., the user may manually change the volume setting of the cellular phone to a low setting, the phone may have pre-stored profiles that may contain saved settings of features such as volume, ringer, key tones, etc, the cellular phone may measure the level of ambient noise present in the environment of the user.

In step 230, the amplifier circuit detects the user selected volume setting. As shown in FIG. 1, the user selected volume setting 140 is the control for the adjustable gain amplifier 120.

In step 240, the gain of the adjustable gain amplifier 120 is established according to the user selected volume setting 140 established in step 220. The level of gain applied by the amplifier is inversely proportional to the user selected volume setting 140. Thus, when a low volume setting is selected as in step 220, the gain of the adjustable gain amplifier 120 is set at a high level. The high level of gain ensures sufficient amplification of the user's voice, even if spoken at a low volume.

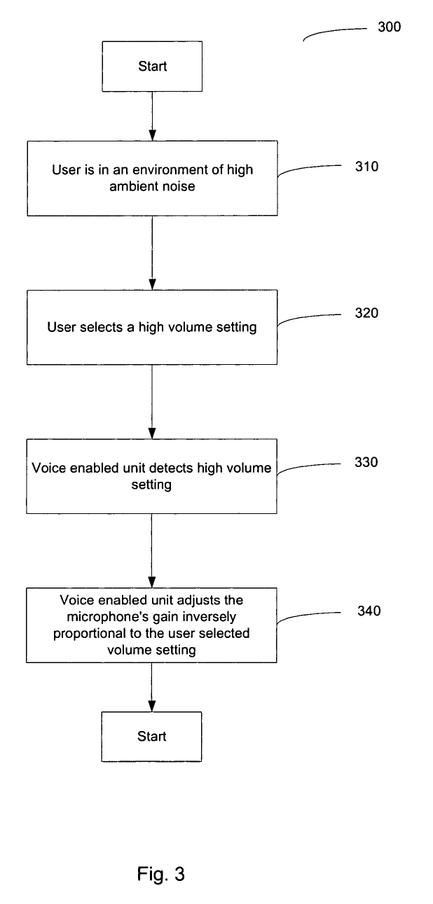

FIG. 3 shows a further exemplary embodiment of a method according to the present invention. The embodiment of FIG. 3 is an exemplary method that adjusts the gain of an amplifier according to user selected settings when the user is in an environment with a high level of ambient noise. The method is described with reference to the system described in FIG. 1. Those of skill in the art will understand that other systems having various configurations may be used to execute the exemplary method.

In step 310, the user of the device (e.g. cellular phone) enters an environment that has a high level of background noise. This may include settings such as a manufacturing facility, a sporting event, an airport, a moving train, etc. In these types of settings, it is likely that the user of a cellular phone would use a higher volume setting on his/her phone and would be speaking at a loud volume.

In step 320, the user selects a high volume setting (e.g. user selected volume setting 140). This action may be accomplished in a variety of manners. The user may manually change the volume setting of the cellular phone to a high setting. The phone may have pre-stored profiles that may contained saved settings of features such as volume, ringer, key tones, etc. The cellular phone may have a separate microphone to measure the level of ambient noise present in the environment of the user.

In step 330, the amplifier circuit detects the user selected volume setting. As shown in FIG. 1, the user selected volume setting 140 is the control for the adjustable gain amplifier 120.

In step 340, the gain of the adjustable gain amplifier 120 is established according to the user selected volume setting 140 established in step 320. The level of gain applied by the amplifier is inversely proportional to the user selected volume setting 140. Thus, when a high volume setting is selected as in step 320, the gain of the adjustable gain amplifier 120 is set at a low level. The low level of gain ensures that the background noise will not be over-amplified, and already loud volume of the user's voice will not be overpowering.

The present invention provides several advantages over existing fixed gain amplification systems and methods for voice-enabled mobile devices. As described above, the adjustable gain amplifier will improve the sound quality of cellular phones in environments of varying ambient noise. In traditionally quiet locations where a user is likely to speak at a softer volume, there would be greater amplification to ensure sufficient amplification of the user's voice. In contrast to quiet environs, in situations where ambient and background noise is high, a user is likely to speak at an increased volume. The lower gain value for amplification in this situation by the present invention will ensure that high volume of background noise is not amplified, and that the user's already loud volume is not amplified to the point of being overpowering.

In addition, the variable gain amplifier helps to maintain the user's voice level at a constant volume for the person at the receiving end. That is, as the natural volume of the user's speech changes because of various conditions (e.g., ambient noise in the environment) the variable gain amplifier system is used to maintain the volume of the speech for the receiver at a constant level by applying different levels of gain to the different volume of speech.

The present invention is also useful in systems having acoustic echo cancellers (“AECs”) because the present invention allows for a flat speaker to microphone coupling ratio. In traditional fixed microphone gain designs, the speaker to microphone coupling is increased as the user volume is increased. The exemplary embodiments of the present invention eliminate this problem by having a substantially flat coupling.

Moreover, the flat speaker to microphone coupling allows for increased efficiency of echo suppressor systems. In addition to AEC, a half duplex suppressor system may be used in conjunction with the present invention. Such a system will not experience clipping of downlink audio when volume is at the maximum volume setting.

It will be apparent to those skilled in the art that various modifications and variations can be made in the structure and the methodology of the present invention without departing from the spirit or scope of the invention. Accordingly, various modifications and changes may be made to the embodiments without departing from the broadest spirit and scope of the present invention as set forth in the claims that follow. The specification and drawings are accordingly to be regarded in an illustrative rather than restrictive sense.

What is claimed is:

1. A mobile device, comprising:
a microphone to receive audible input; and
an audio circuit to transform the audible input into an electrical signal, the audio circuit including a variable gain amplifier to amplify the electrical signal, a gain of the variable gain amplifier being set based on a volume setting of the mobile device.

2. The mobile device of claim 1, wherein the gain is inversely proportional to the volume setting.

3. The mobile device of claim 1, wherein the mobile device is one of a cellular phone, a VoIP enabled device, a PDA and a laptop computer.

4. The mobile device of claim 1, wherein the variable gain amplifier is one of an operational amplifier and an integrated circuit.

5. The mobile device of claim 1, wherein the variable gain amplifier includes a plurality of fixed gain amplifiers.

6. The mobile device of claim 1, wherein the volume setting is manually set by a user of the device.

7. The mobile device of claim 1, further comprising:
a memory storing a profile, the profile including the volume setting.

8. The mobile device of claim 1, further comprising:
noise measuring circuitry to measure an ambient noise level, the volume setting being based on the ambient noise level.

9. The mobile device of claim 1, wherein the audio circuit further includes one of a filter, a mixer, a modulator, and a transmitter.

10. The mobile device of claim 1, further comprising:
an echo suppressor system.

11. A method, comprising:
receiving an audible signal;
setting a gain of a variable gain amplifier, the gain being based on a volume setting of a mobile device in which the variable gain amplifier resides; and
converting the audible signal to an electrical signal, the converting including amplifying the electrical signal with the variable gain amplifier.

12. The method of claim 11, wherein the gain is set inversely proportional to the volume setting.

13. The method of claim 11, wherein the variable gain amplifier is one of an operational amplifier and an integrated circuit.

14. The method of claim 11, wherein the variable gain amplifier includes a plurality of fixed gain amplifiers.

15. The method of claim 11, further comprising:
receiving an input from a user of the mobile device to set the volume setting.

16. The method of claim 11, further comprising:
storing a profile, the profile including the volume setting.

17. The method of claim 11, further comprising:
measuring an ambient noise level; and
setting the volume setting being based on the ambient noise level.

18. An arrangement, comprising:
a receiving means to receive an audible input;
a transforming means to transform the audible input to an electrical signal, the transforming means including a variable gain means to provide the electrical signal with a variable gain based on a volume setting.

19. The arrangement of claim 18, wherein the variable gain is inversely proportional to the volume setting.

20. The arrangement of claim 18, further comprising:
a transmitting means to transmit the electrical signal.

21. The arrangement of claim 17, further comprising:
a means to set the volume setting.
